(19) United States
(12) Patent Application Publication
(10) Pub. No.: US 2015/0061568 A1
(43) Pub. Date: Mar. 5, 2015

(54) Portable Solar-Powered Generator

(71) Applicant: Armando Martinez, Harper, TX (US)

(72) Inventor: Armando Martinez, Harper, TX (US)

(21) Appl. No.: 14/010,539

(22) Filed: Aug. 27, 2013

(51) Int. Cl. H01L 31/052; H02J 7/35

(52) U.S. Cl. CPC H01L 31/0522; H02J 7/355
USPC 320/101; 136/246

(57) ABSTRACT

An improved portable solar-powered generator is disclosed herein. Specifically, an improved portable solar-powered generator comprises a plurality of solar panels capable of absorbing and converting photons into direct current energy, wiring attached to solar panels capable of outputting direct current energy from solar panels, and a controller capable of receiving direct current energy by wiring transferred from solar panels, as the controller can be capable of receiving, measuring and distributing the electrical load of the direct current. The improved portable solar-powered generator further comprises a battery receiving direct current energy from the solar panels by way of controller, as the battery can be capable of storing and transferring direct current energy. Additionally, an improved solar powered generator comprises an analog to digital converter capable of converting the direct current energy received from the battery into alternating current. Finally, an improved solar powered generator further comprises a plurality of power outlets capable of adapting the transfer of alternating current to external appliances and a covering, in which solar panel, controller, battery, analog to digital converter and power outlets are affixed together as a unibody.

### BACKGROUND

This disclosure relates to an improved portable solar-powered generator. However, such discussion of an improved portable solar-powered generator is solely exemplary, and not limiting.

With the rise of technology, electricity has become a resource that modern society cannot function without. Throughout history, methods for using electrical power have evolved. Developments in electrical circuits, wiring and batteries in homes have evolved to provide power for a variety of electrical devices that perform functions, which include heating, lighting, and cooking Entire cities have developed power grid systems to provide electricity for millions of homes.

However, resources, which provide electricity, such as coal and fossil fuels are expensive and finite. Additionally, current sources for electricity may be stationary and inconvenient to access. Furthermore, shortages, power outages can render conventional electrical sources ineffective.

Eventually, solar-powered generators developed as backup sources of power for ordinary generators, as well as, isolated off-grid rural locations. Solar panels, which could harness free energy from the sun, came to be used as sources which could induce an electrical current.

Today, solar-powered generators are sources of energy for a variety of needs. However, today's solar-powered generators contain their share of problems. They are inconveniently assembled as multiple pieces, as opposed to a set unit. They are also either immovable, or difficult move. If solar-powered generators are portable, they tend to run out quickly and are unable to provide vast amounts of power for larger-scale needs. Furthermore, today's solar-power generators can be damaged by rain, wind, and other weather elements.

Thus, it would be useful for an improved portable solar-powered generator.

### SUMMARY

An improved portable solar-powered generator is disclosed herein. Specifically, an improved portable solar-powered generator comprises a plurality of solar panels capable of absorbing and converting photons into direct current energy, wiring attached to solar panels capable of outputting direct current energy from solar panels, and a controller capable of receiving direct current energy by wiring transferred from solar panels, as the controller can be capable of receiving, measuring and distributing the electrical load of the direct current. The improved portable solar-powered generator can further comprise a battery receiving direct current energy from the solar panels by way of controller, as the battery can be capable of storing and transferring direct current energy. Additionally, an improved solar powered generator comprises an analog to digital converter capable of converting the direct current energy received from the battery into alternating current. Finally, an improved solar powered generator further comprises a plurality of power outlets capable of adapting the transfer of alternating current to external appliances and a covering, in which solar panel, controller, battery, analog to digital converter and power outlets are affixed together as a unibody.

### BRIEF DESCRIPTION OF THE DRAWINGS

FIG. 1 illustrates a portable solar-powered generator.

FIG. 2 illustrates a side surface of portable solar-powered generator with a solar panel.

FIG. 3 illustrates a side solar panel extended from side surface of portable solar-powered generator

FIG. 4 illustrates a propping mechanism on a door.

FIG. 5A illustrates an embodiment of side surface solar panel extension angled with top solar panels.

FIG. 5B illustrates another embodiment of side surface solar panel extension angled with top solar panels.

FIG. 5C illustrates another embodiment of side surface solar panel extension angled with top solar panels.

FIG. 5D illustrates another embodiment of side surface solar panel extension angled with top solar panels.

FIG. 6 illustrates a portable solar-powered generator opened with inner recess exposed.

FIG. 7 illustrates an arrangement of breakers and batteries.

FIG. 8 illustrates an analog to digital converter.

FIG. 9A illustrates an exploded view of breaker and positive terminal.

FIG. 9B illustrates an exploded view of negative terminal.

FIG. 10 illustrates a wire and a breaker disconnecting system.

FIG. 11 illustrates a power outlet.

FIG. 12A illustrates an embodiment of a handheld portable solar-powered generator.

FIG. 12B illustrates an handheld portable solar-powered generator open.

### DETAILED DESCRIPTION

Described herein is an improved portable solar-powered generator. The following description is presented to enable any person skilled in the art to make and use the invention as claimed and is provided in the context of the particular examples discussed below, variations of which will be readily apparent to those skilled in the art. In the interest of clarity, not all features of an actual implementation are described in this specification. It will be appreciated that in the development of any such actual implementation (as in any development project), design decisions must be made to achieve the designers' specific goals (e.g., compliance with system- and business-related constraints), and that these goals will vary from one implementation to another. It will also be appreciated that such development effort might be complex and time-consuming, but would nevertheless be a routine undertaking for those of ordinary skill in the field of the appropriate art having the benefit of this disclosure. Accordingly, the claims appended hereto are not intended to be limited by the disclosed embodiments, but are to be accorded their widest scope consistent with the principles and features disclosed herein.

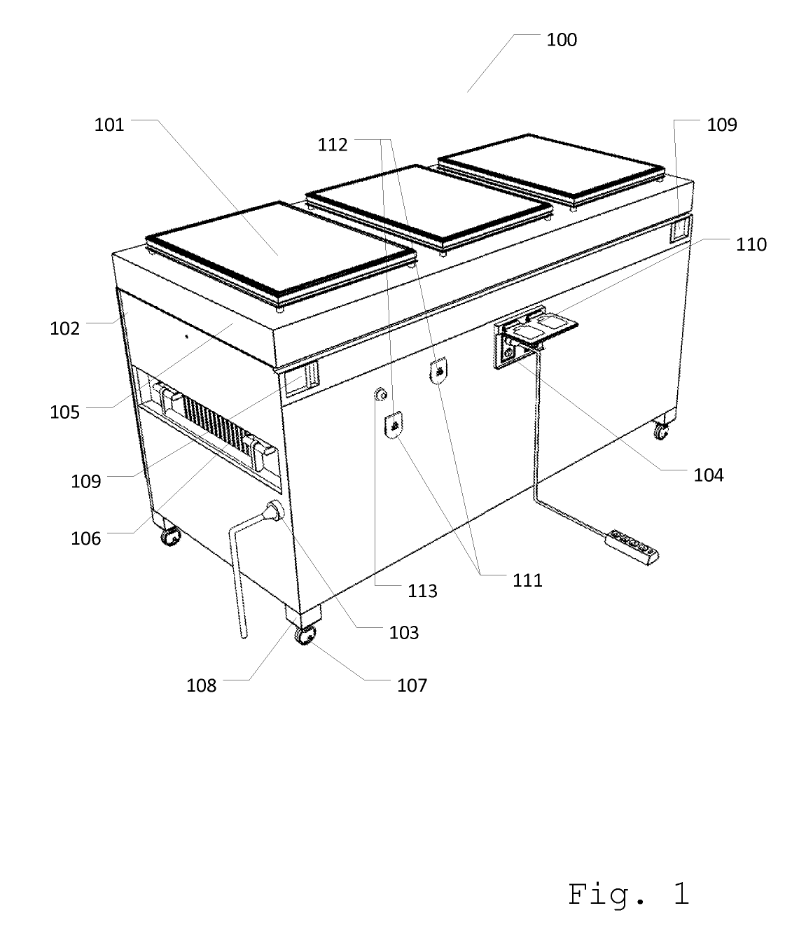

FIG. 1 illustrates a portable solar-powered generator 100. Portable solar-powered generator 100 can act as a power source for any device that requires electrical power to operate and is capable of plugging into an electrical power outlet. Portable solar-powered generator 100 can comprise a plurality of solar-powered panels 101. Solar-powered panels 101 can convert ultraviolet radiation from sunlight into usable energy. Solar-powered panels 101 can be positioned on portable solar-powered generator 100 for access to sunlight. In one embodiment, solar-powered panels 101 can be placed on an outside surface of portable solar-powered generator 100.

Multiple solar panels 101 can be in an embodiment of arrangements. In one embodiment, portable solar-powered generator 100 can have an arrangement of three solar panels 101 positioned on outer surface. Solar panels 101 can work in coordination with the rest of portable solar-powered generator 100 to maximize energy retention and optimize energy transfer efficiency.

Arrangements of solar panels 101 can be crafted to accommodate efficiency in the transfer of energy. In one embodiment, solar panels 101 can be arranged in a straight line to form a row and placed on the very top surface of portable solar-powered generator 100. In one embodiment, solar panels 101 can be angled, as needed, to accommodate absorption of sunlight. In another embodiment, solar panels 101 can be organized in a folding arrangement, as opposed to a flat arrangement, where at least one or more panels can be angled and attached together to capture more sunlight. Furthermore, solar panels 101 can be arranged in a series circuit, in one embodiment, and a parallel circuit, in another embodiment. In one embodiment, concentrators that focus sunlight with mirrors can be applied to solar panels 101.

Portable solar-powered generator 100 can be encased in a covering 102. Covering 102, in one embodiment, can comprise a door 105. Door 105 can be capable of closing and opening access to a recessed interior to be described further below. Covering 102 can comprise, but is not limited to, metal, plastic, or wood, as well as, any combination of such components. Covering 102 can house components of solar-powered generator 100, which will be discussed further below. Covering 102 can also serve as both a protective shield for components of portable solar-powered generator 100. Covering 102 can also be capable of housing storage for additional accessories, as described below. In one embodiment, covering 102 can comprise wheels 107, legs 108, and/or other attachments that allow portability of portable solar-powered generator 100. Furthermore, covering 102 can have locks 109 on surface to secure door 105. In one embodiment, locks 109 can be placed on sides of door 105 for accessibility.

In other embodiments, covering 102 can also be made to resist weather elements, which can include, but is not limited to, rain, sand, wind, snow, heat and/or a combination of all elements. In one embodiment, covering 102 can be made waterproof by use of sealants over any holes created by affixing components, such as, but not limited to, solar panels 101 to portable solar-powered generator 100. Furthermore, covering 102 can comprise ventilation strip 106. Ventilation strip 106 can comprise a plurality of holes or slits on surface for the prevention of overheating. Also, window strips in ventilation system are tilted outward to keep rain from coming in and force it to flow out. In one embodiment, inside walls of covering 102, can comprise insulation to control heat and temperature in conjunction with ventilation system. Insulation in covering 102 can also be in bottom surface of solar powered generator 100 for bracing and support of components, as well as to allow covering 102 the possibility of floating if flooded, for example.

Furthermore, a ground wire 103 can be attached to portable solar-powered generator 100 at outside surface of covering 102. Ground wire 103 can comprise a metal wire that can be insulated. Ground wire 103 can be attached to floor, ground surface or any terrain surface upon which portable solar-powered generator 100 can be placed or positioned. As a result, ground wire 103 can help prevent electrical shock or damage to portable solar-powered generator 100.

Additionally, portable solar-powered generator 100 can comprise a power outlet 104. Power outlet 104 can allow electronically powered devices to attach to portable solar-powered generator 100 to gain access to energy. In one embodiment, power outlet 104 can comprise an electronic outlet which can be attached to by plug. As a result, electronically powered devices can operate, while plugged into power outlet 104, or store energy, if a battery is contained within electronically powered device. Power outlet 104 can comprise of plug-in inserts, in which electrical devices can attach by a plug-in cord. Power outlet 104 can further comprise outlet covers 110, which can protect outlet from exposure to the elements. In one embodiment, outlet covers 110 can be attached to covering 102 and retractable, while in another embodiment outlet covers 110 can be detachable.

In one embodiment, covering 102 can comprise additional 12-volt outlets 111. 12-volt outlets can comprise 12-volt covers 112. 12-volt covers 112 can encompass surface of 12-volt outlets 111, protecting them from exposure to the elements. In one embodiment, 12-volt covers 112 can be made of plastic, for example.

Covering 102 can also comprise spring lighter 113. Spring lighter 113 can be a cylinder with a hot wire and springing mechanism. Spring lighter 113 can be built into covering 102 and connected to solar panels 101. Spring lighter 113 can be pushed in to activate heating up of hot wire from solar panels 101. As a result, spring lighter 113 can light up hot wire and provide a fire source for user. In one embodiment, spring lighter 113 can be a conventional cigarette lighter found in most automobiles.

Solar panels 101 can comprise semiconductor materials, which can include, but is not limited to, crystalline solids and/or silicon. The units of the semiconductor materials can be arranged as a plurality of solar cells. As sunlight, in the form of photons, touches the surface of solar panel 101, energy is absorbed by the semiconductor material in the solar cells. As more sunlight is absorbed, the electrons in the solar cells cause electrons to move and induce an electric current.

Solar cells can be protected by a layer or screen of materials, which can include, but is not limited to, glass and/or clear plastics. Beneath cover glass, solar panel 101 can have an antireflection coating, affixed by a transparent adhesive on top of the semi conductor solar cells. Furthermore, wiring can be placed beneath the semiconductors with a back casing comprising insulating material to accommodate current induction. The current is transferred from the solar panels 101 through wiring 202 that may contain conductive metals, including, but not limited to, copper or silver. Electrical connections can be made in series or parallel arrangements to achieve appropriate voltage and/or current level.

Solar panels 101 can comprise groups of cells, which form solar modules. Similarly, solar panels 101 can also comprise groups of solar modules, which form solar arrays. Solar cells in solar panels 101 can comprise cell characteristics which can include, but are not limited to, rigid, semi-flexible or thin-film cells. Solar cell characteristics can determine energy density, which is the efficiency of peak power output per unit of surface area, i.e., watts per square foot.

Furthermore, frame encasing solar panel 101 can be made of materials such as any type of aluminum and/or plastic. In one embodiment, types of solar panels 101 can be weatherproof, as solar-powered generator can be built to resist rain, wind, dust, ice, and/or snow. For example, sealant can be applied to portable solar-powered generator 100 to stop rain. Since solar cells of solar panels 101 become less efficient in voltage output from extreme temperatures and heat, temperature controlling mechanisms can be applied to solar panels 101, as well as solar-powered generator 101, in general.

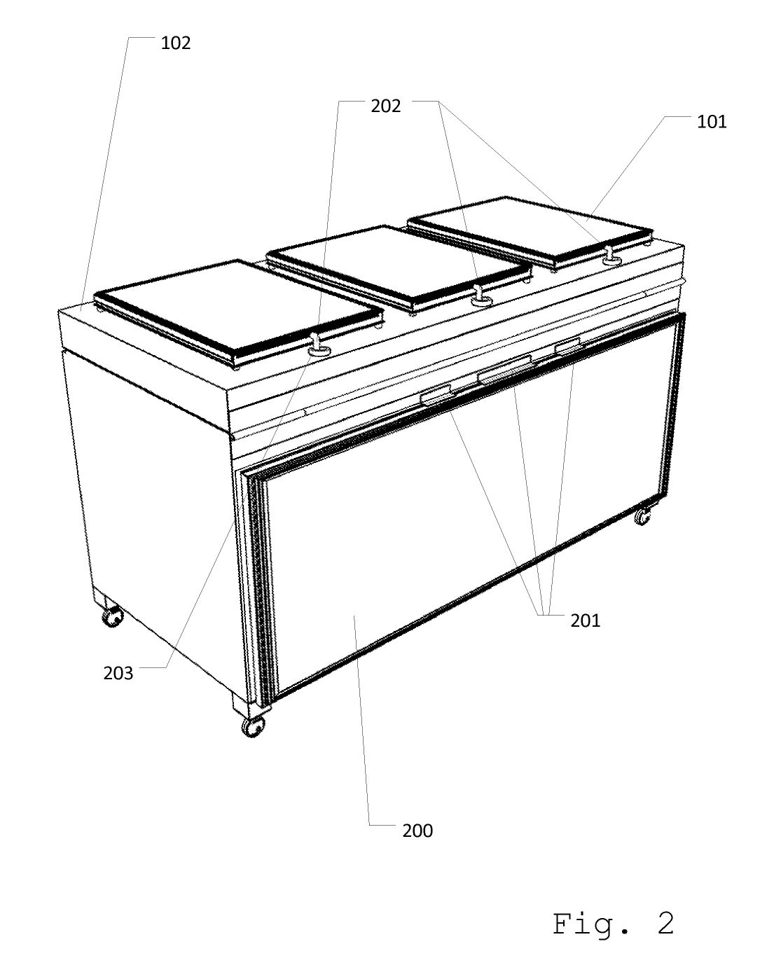

FIG. 2 illustrates a side surface of a portable solar-powered generator 100. Along with solar panels 101 on top surface of portable solar-powered generator 100, side surface can have an additional side solar panel 200 attached to a side surface adjacent to solar panels 101. In conjunction with solar panels 101, side solar panel 200 can allow solar powered generator 100 to power and recharge electrical appliances quickly. In one embodiment, side solar panel 200 can be a 200 watt solar panel. In one embodiment, a plurality of hinges 201 can be attached to top portion of the side surface. As a result, side solar panel 200 can be movable at hinge 201.

Solar panels 101 can transfer power by wiring 202. Wiring 202 can be but is not limited to, metal coil encased in a protective layer that can further comprise but is not limited to rubber. Wiring 202 can transfer power to components inside solar power generator 100, to be discussed further below. Rubber stoppers 203 can prevent wiring 202 from touching surface and also keep water out from entering covering 102 and damaging solar power generator 100.

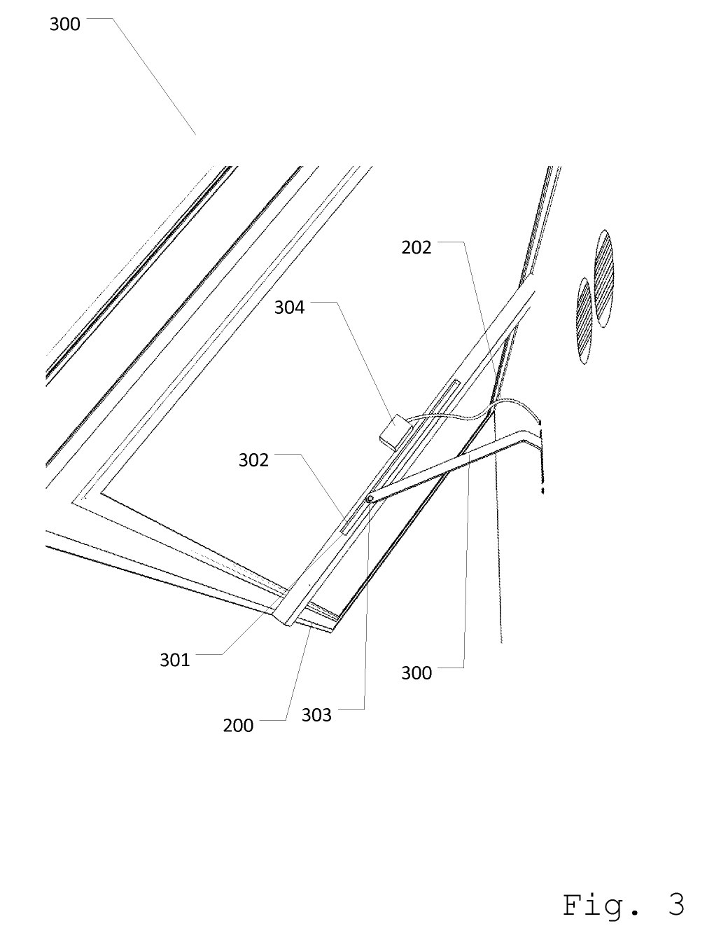

FIG. 3 illustrates a side solar panel 200 extended from side surface of portable solar-powered generator 100. A pneumatic closer 300 can elevate side solar panel 200 at a number of degrees of tilt. Pneumatic closer 300 can be a rod affixed to bottom surface of side solar panel 200. In various embodiments, pneumatic closer 300 can be a variety of lengths, as well as various angles as needed for desired angle of side solar panel 200. In one embodiment, pneumatic closer 300 can have hydraulic support.

In one embodiment, pneumatic closer 300 can be attached to a track system 301. In another embodiment, track system 301 can be mounted, or otherwise affixed, to a surface of side solar panel 200. Track system 301 can comprise a slot 302 and a track attachment 303. In one embodiment, track attachment 303 can comprise a wheel that fits in the width of slot 302. In another embodiment, track attachment 303 can be attached to pneumatic closer 300. To lift side solar panel 200, pneumatic closer 300 can elevate upwards and move track attachment 303 along slot 302. In one embodiment, track attachment 303 can be locked into a spot on slot 302.

In one embodiment, side solar panel 200 can comprise a battery bank 304. Battery bank 304 can act as a breaking mechanism for side solar panel 200. In one embodiment, battery bank 304 can also store additional power captured from side solar panel 200. Wiring 202 can connect to battery bank 305 and connect side solar panel to internal components of solar powered generator 100, which will be discussed further below. Battery bank 305 can be capable of breaking flow of electricity between side solar panel 200 to additional components of portable solar powered generator 100, to be discussed further below.

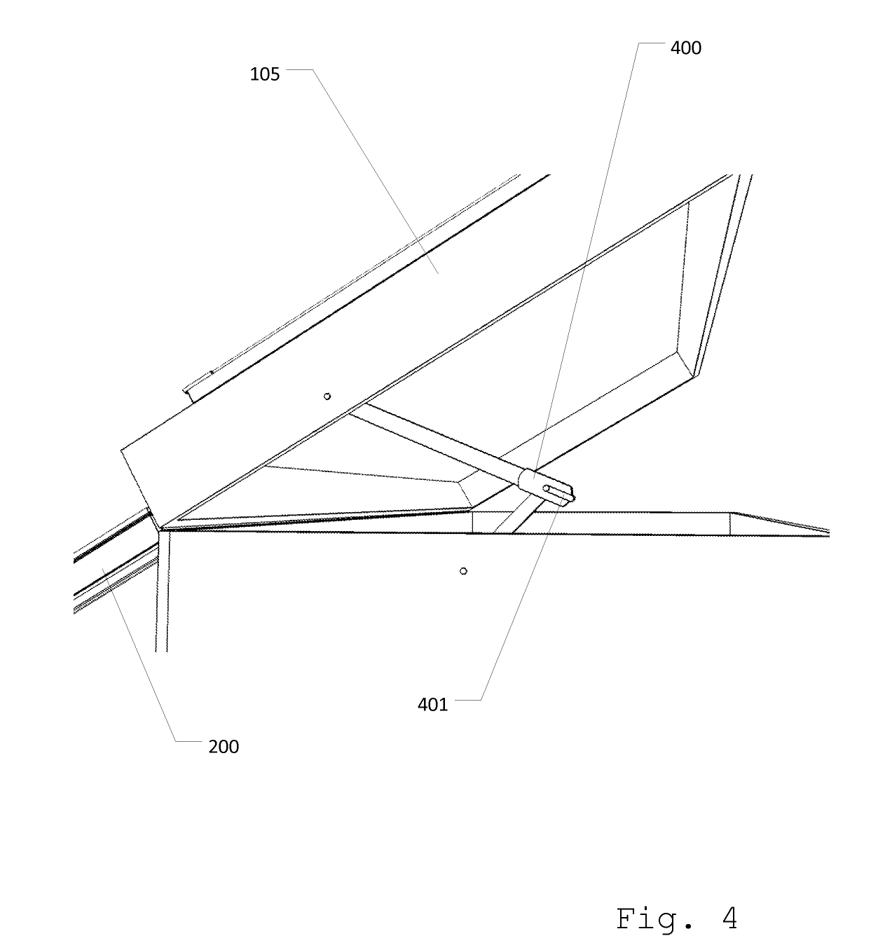

FIG. 4 illustrates a propping mechanism 400 on door 105. Propping mechanism 400 can be a plurality of rods or latches connected to door 105. In one embodiment, propping mechanism 400 can form an elbow shape that can hinge. In one embodiment, a pin 401 can be inserted into propping mechanism 400. As a result, door 105 can be held open. As a result, solar panels 101 can be angled to face sideways to capture light as needed, allowing better angling of sunlight to directly hit their surface. In one embodiment, propping mechanism 400 can be adjustable to coordinate angling of door 105 with side solar panel 200, as illustrated further below. In one embodiment, door 105 can be angled to allow reflection of captured light to bounce off side solar panel 200 to maximize sunlight input.

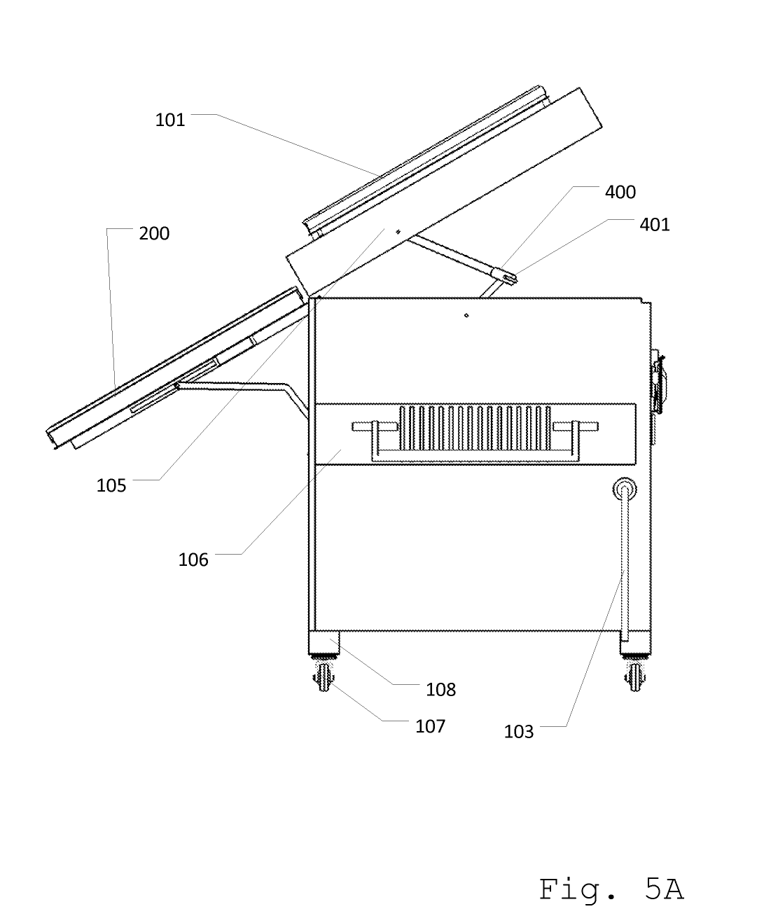

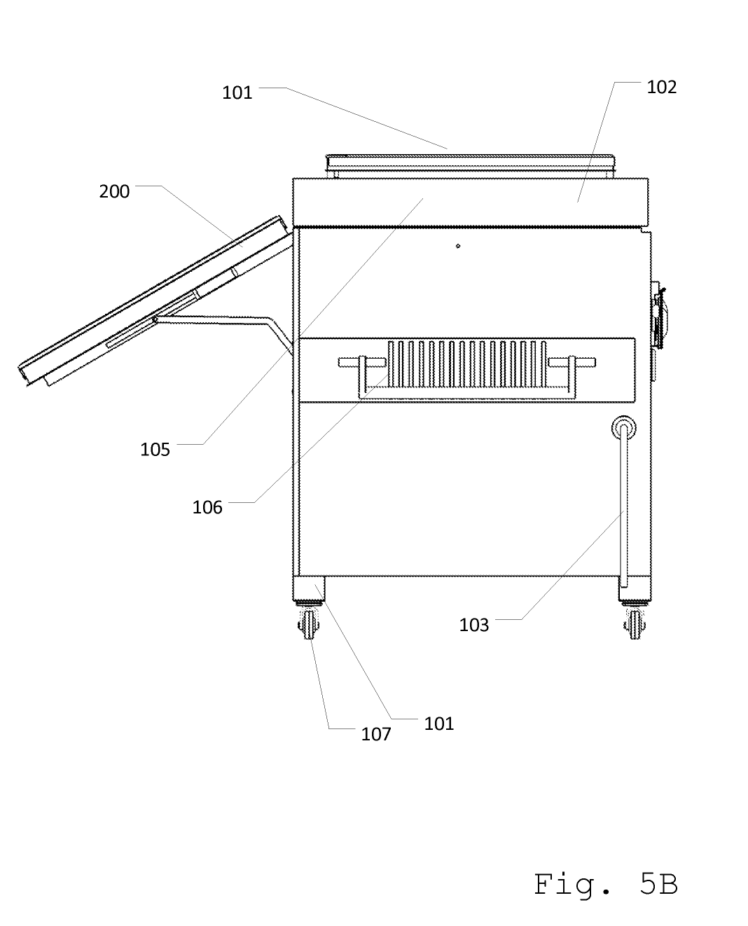

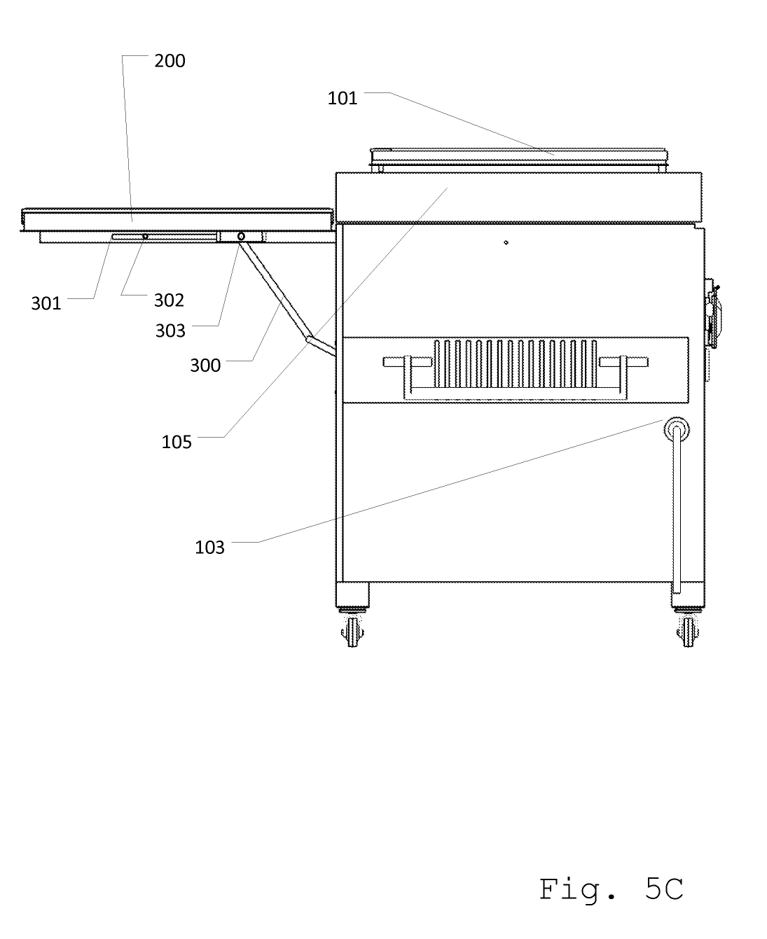

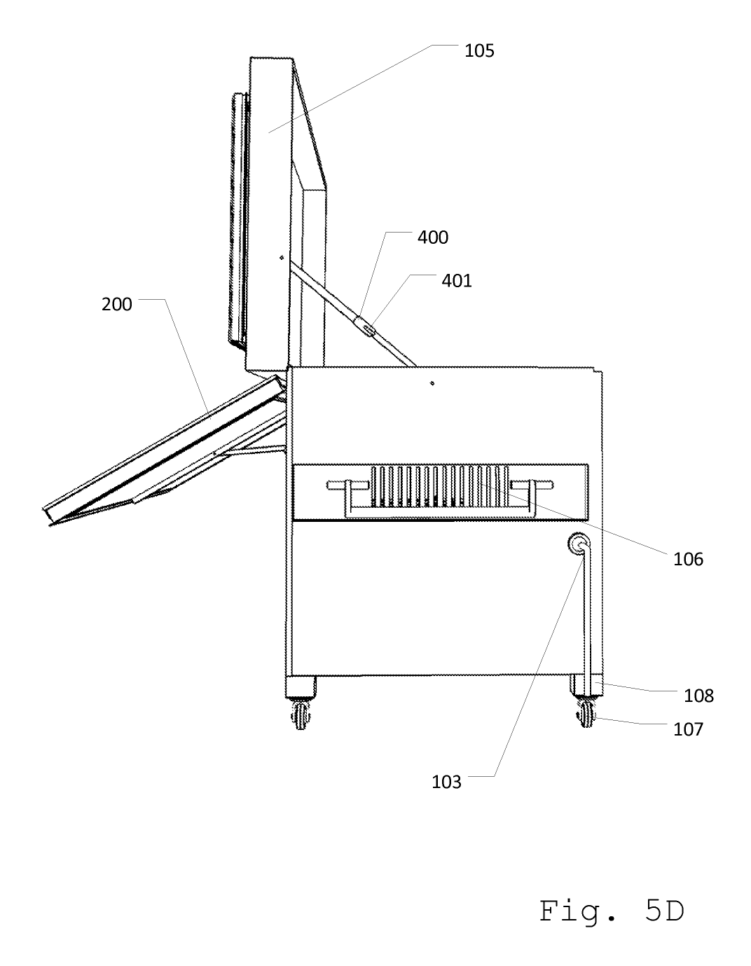

FIG. 5A illustrates an embodiment of side solar panel 200 and top solar panels 101 angled upward. Solar powered generator 100 can have various combinations of positions in which side solar panel 200 and door 105 can be angled in coordination with each other to maximize sunlight input. In one embodiment, side solar panel 200 can be tilted downward, by pneumatic closer 300, while door 105 is angled upward by propping mechanism 400. In one embodiment, propping mechanism 400 and pneumatic closer 300 can position door 105 and side solar panel 200, respectively in such a way that each are angled together to form a continuous surface. In such an embodiment, the tilting of both side solar panel 200 and door 105 can allow top panels 101 to be facing outward to avoid rain build up and have water flow down away from solar-powered generator 100.

FIG. 5B illustrates another embodiment of side solar panel 200 angled with door 105. In one embodiment, side solar panel 200 can tilt upward by pneumatic closer 300. At the same time, door 105 can remain closed. Such embodiment can optimize sunlight retention depending on time of day and positioning of sun or other environmental surroundings in which solar-powered generator 100 can be placed.

FIG. 5C illustrates another embodiment of side solar panel 200 angled with door 105. In one embodiment, side solar panel 200 can be positioned into a flat, horizontal, table top shape by pneumatic closer 300. At the same time, door 105 can remain closed. Such embodiment can optimize sunlight retention depending on time of day and positioning of sun or other environmental surroundings in which solar-powered generator 100 can be placed.

FIG. 5D illustrates another embodiment of side solar panel 200 angled with door 105. In one embodiment, door 105 can be fully extended open by propping mechanism 400. At the same time, side solar panel 200 cannot form flat horizontal position. Such embodiment can optimize sunlight retention depending on time of day and positioning of sun or other environmental surroundings in which solar-powered generator 100 can be placed. Furthermore, such embodiment can allow solar-powered generator 100 to catch sunlight reflected from other surfaces that might otherwise go unused.

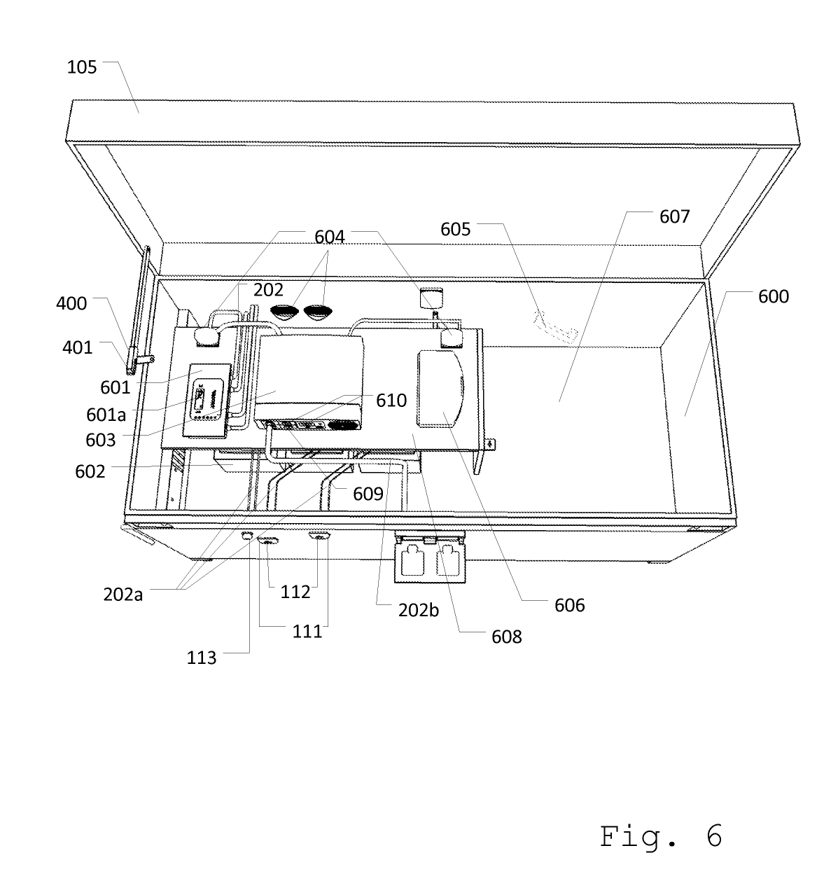

FIG. 6 illustrates a portable solar-powered generator 100 opened with inner recess 600 exposed. Inner recess 600 can house a controller 601. Controller 601 can be attached to wiring 202 that transfers energy from solar panels 101 and/or side solar panel 200. Controller 601 can distribute energy received from solar panels 101 equally to the rest of components described below. Controller 601 can plug directly into solar panels 101 and/or side solar panel 200. Controller 601 can have electrical input and output capabilities. Furthermore, controller 601 can comprise controller display 601a. In one embodiment, controller display 601a can be capable of displaying voltage levels from current of solar panels 101 and/or side solar panel 200. In another embodiment, when solar panels 101 and/or side solar panel 200 are angled differently, controller display 601a can display reflected voltage changes to user.

Inner recess 600 can house a battery 602. Battery 602 can comprise a plurality of batteries that can be attached to solar panels 101 by wiring 202. Wiring 202 can be a cable and/or a rod of metal used to bear mechanical loads and carry electrical or telecommunications signals. Battery 602 can be powered by solar panel 101 and produce direct current through wiring 202. Battery 602 can receive electrical signals through wiring 202 initially from solar panels 101. Electrical signals can then send power to battery 602. Also, battery 602, in one embodiment, can be, but is not limited to, a 12 volt battery, which can comprise a deep cycle or continuous cycle. Battery 602 can power appliances, by transferring electrical signals. As battery 602 sends electrical signals through wiring 202, electrical signals can be sent as direct current.

Controller 601 can prevent battery 602 from either having too little or too much electrical load at any given time. Controller 601 can interact with solar panels 101 by powering battery 602 and relieving electrical load given to battery 601 from solar panels 101 and/or side panel 200. In one embodiment, side panel 200 can have wiring 202 from controller 601 and serve as the output to battery 602.

Inner recess 600 can also comprise an analog to digital (A/D) converter 603. As the path of electrical signals continues, wiring 202 can attach battery 602 to analog to digital convertor 603. Analog to digital converter 603 can convert direct current electrical signals from an analog format to a digital format. Analog to digital convertor 603 can make electrical current usable by various direct plug-in electrical appliances. Analog to digital converter 603 can comprise electrical sockets 609, in which electrical devices can attach by plug. Analog to digital converter 603 can also comprise a display 610.

At the same time, wiring 202 can connect battery 601 to terminals 604. Terminals 604 can be a conductive surface upon which wiring 202 can attach. Terminals 604 can be attached to wiring 202 to serve as a breaking point in electrical distribution from solar panels 101 and side panel 200. In one embodiment, terminals 604 can be placed between wiring 202 of battery 604 and controller 601, while in another embodiment, terminals 604 can be placed between wiring 202 and A/D converter 603. As a result, terminals 604 can put less stress on battery. In one embodiment, terminals 604 can be encased in some form of insulation for safety. In another embodiment, terminals 604 can prevent fire and allow space between wiring 202 and surface of inner recess 600 without allowing current to touch covering 102 and/or inner recess 600 of solar powered generator 100.

In one embodiment, inner recess 600 can comprise a crank mechanism 605. Crank mechanism 605 can be but is not limited to, a rotating rod connected to side solar panel 200. In one embodiment, crank mechanism 605 can be affixed to track system 301 underneath side solar panel 200. Crank mechanism 605 can control degree of movement of side solar panel 200 by rotation. Upon rotation in one direction, in one embodiment, crank mechanism 605 can vertically lift track system 301. As a result, side solar panel 200 can, in turn, cause side solar panel 200 to vertically extend upwards along with track system 301. Upon rotation in an opposite direction, crank mechanism 605 can lower side solar panel 200 by causing track system 301 to retreat angularly backwards toward inner recess 600. In conjunction, pneumatic closer 300 can prop side solar panel 200 at desired level. In one embodiment, crank mechanism can be stored inside inner recess 600. In one embodiment, cranking mechanism can comprise accessories such as but are not limited to shocks, awnings and/or latches. As a result, side solar panel 200 can not only be angled or tilted upward, but stabilized securely.

In one embodiment, aside from wiring 202 from terminals 604, A/D convertor can further connect to wiring 202 attached to a power outlet 104. Power outlet 104 can be affixed to any surface of covering 102 for accessibility of electrical appliances. Electrical appliances with power cords can access electricity by plugging in to power outlet 104. In one embodiment power outlet 104 can be plugged directly from A/D converter 603. In addition, A/D converter 603 can be placed on a shelf 608 to keep it separate from battery 602 and assist with arrangement and organization.

While one course of wiring 202 can lead from battery 602 to A/D converter 603, another course of wiring 202 can connect battery 602 to 12-volt outlets 111. Wiring 202a to 12-volt outlets 111 can be separately configured from wiring 202b from a/d converter 602 to power outlet 104, so as to prevent interference between 12-volt outlets 111 and power outlet 104.

Inner recess 600 can also comprise an accessory storage compartment 606. Accessory storage compartment 606 can house objects, such as, but not limited to, tools, devices, and/or spare parts necessary for installation of accessories or repair of solar-powered generator 100, for example. Furthermore, inner recess 600 can also comprise a general storage area 607 to house any additional accessories or other objects, as desired by user.

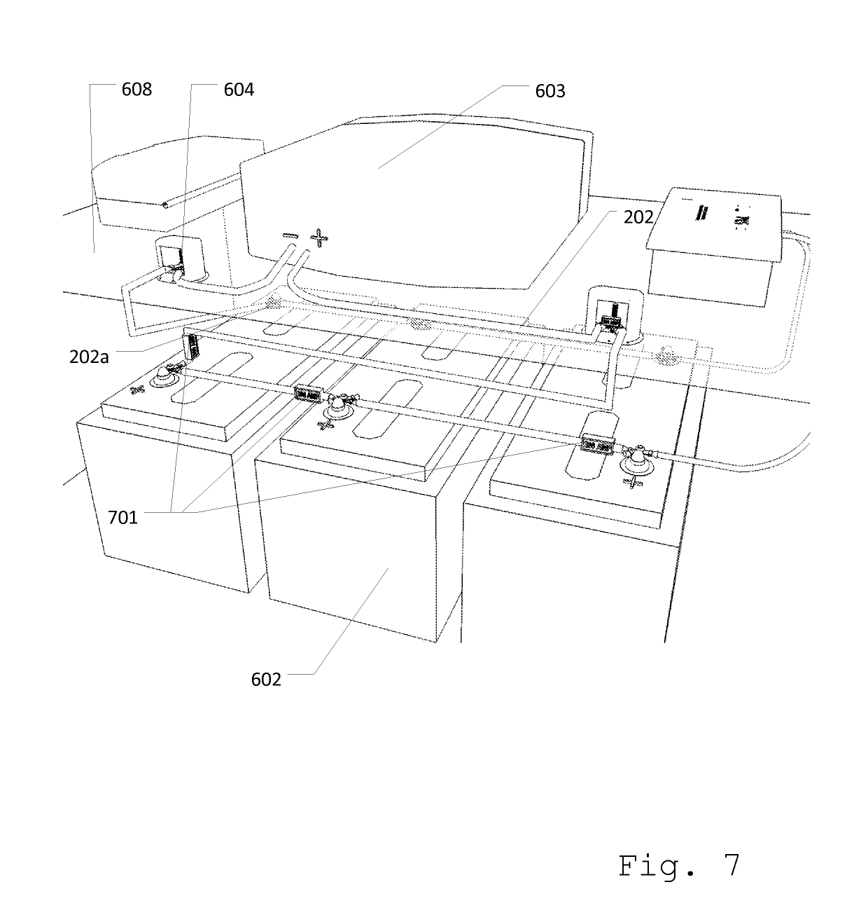

FIG. 7 illustrates a close-up view of a plurality of breakers 701 connected to batteries 602. Breakers 701 can be a device that protects an electrical circuit from overload or short circuits. Breakers 701 can operate automatically and can detect any fault and can interrupt current flow to protect portable solar-powered generator 100. Portable solar-powered generator 100 can include a plurality of more batteries 602, which can be rechargeable. Battery 602 can comprise, but is not limited to, Gel Cell, lithium-ion, lithium-sulfur, zinc-carbon, lead-acid, alkaline battery, or an ultracapacitor. In one embodiment, battery 602 can be a 12-volt battery. Wiring 202 running from controller 601 can attach to electrodes 700 of battery 602.

In one embodiment, wiring 202 from controller 601 can be connected to battery 602 as a whole. In such embodiment, the positive charge of one battery 602 and negative charge of another battery 602 with additional wiring 202 traveling across positives of each battery 602 and negatives of each battery 602. In addition, wiring 202 from solar panels 101 and controller 601 can be connected to each battery 602 individually, in another embodiment.

Additionally, batteries 602 can also be organized in various arrangements, which can include, but is not limited to, a partial arrangement or a serial arrangement. Wiring 202 can run from opposite outer ends of battery 602. For example, wiring 202 from side panel 200 can be linked to the positive charge of an outer battery 602 and the negative charge of another battery 602 on opposite end of arrangement of batteries 602. Additional wiring 202 can travel across positive electrodes 700 of each battery 602 and negative electrodes 700 of each battery 602. In such embodiment, configuration of battery 602 can allow solar panels 101 and side panel 200 to charge all the batteries 602 together overall as a system. As a result, the delay in time for recharging batteries 602 can be minimized.

In one embodiment, battery 602 can be placed on wooden surface, so as to prevent contact with any embodiment of covering 102 comprising metallic material, eliminating any potential rusting of metal from battery 602 usage. In an embodiment where covering 102 comprises metallic material, battery 602 can be raised or otherwise positioned to not contact metallic surface of covering 102, as energy of metallic surfaces can drain battery 602. As a result, battery 602 can be in use for much longer than ordinary. Furthermore, in one embodiment, there can be several inches between bottom of covering 102 and location of where battery 602 is situated to prevent flooding in case of potential rain buildup.

In one embodiment, battery 602 can be a sealed gel cell deep-cycle solar battery (92DC). As direct current transfers into battery 602, energy can be stored until necessary. In one embodiment, battery 602 can be a sealed gel cell deep-cycle, which can store the electricity gathered by the solar panels 101. A deep-cycle battery 602 can provide a steady current over a long period of time. Battery 602 can be rechargeable, as power can be drained and recharged several times by electric current. In an embodiment with a plurality of batteries 602, all batteries 602 can be balanced in the same state. Particularly, the ratio of solar panels 101 to batteries 602 can evenly share current load within portable solar-powered generator 100. With a balanced load, specific types of solar panels 101 and arrangement of wiring 202 can interact with battery 602 to keep system controlled and prevent degradation and internal discharge. In an embodiment in where all batteries 602 can be wired together as whole, wiring 202 can be designed to allow battery to have a longer lifespan to be extended over a longer time, instead of a large power jolt. In an embodiment with deep cycle batteries 602, one battery can provide power for at least six hours of heavy duty appliance usage. In an embodiment, wherein multiple deep cycle batteries 602 are wired together, power can be multiplied, allowing for six hours of heavy duty appliance usage per each battery. Hence, for example, three deep cycle batteries 602 can provide at least 18 hours of heavy duty appliance usage.

Battery 602 can comprise various embodiments of battery capacity, which is the limit to the storage of electrical charge in battery 602. Higher amounts of electrode material in battery 602 can determine capacity. If battery 602 is discharged at a high rate, the capacity will be lower. As chemical reactions occur in the battery 602, the magnitude of the current can also affect capacity of battery 602. As a result, the type, number and arrangement of solar panels 101 can determine effectiveness and long-term capacity of battery 602. Moreover in an event wherein problems occur to the electrical circuit, which can be caused by overload or short circuit, breakers 701 that are connected on positive batteries 602 can interrupt the current flow but still allow other batteries remain functional. In addition to the interaction between solar panels 101 with battery 602 through wiring 202, environmental factors, such as temperature and/or moisture, can affect capacity of battery 602. As a result, ventilation and sealing capabilities of covering 102 can also help optimize the storage capacity of battery 602.

In various embodiments, the number of solar panels 101 applied to portable solar-powered generator 100 can be coordinated with the number and/or type of battery 602. In one embodiment, portable solar-powered generator 100 can comprise an arrangement of one solar panel 101 per battery 602, as each solar-powered panel 101 can be individually connected to each battery 602. In one embodiment, multiple solar panels 101 can be connected to each individual battery 602, while in another embodiment, multiple batteries 602 can be connected to each individual solar panel 101.

Additionally, solar panels 101 can prevent overcharging batteries 602 by shutting off once batteries 602 reach full capacity. In one embodiment, solar panels 101 can have a beeping mechanism, which detects when battery 602 reaches full capacity. As a result, solar panels 101 can stop energy flow to prevent overcharging battery 602. Furthermore, as soon as battery power levels decrease by one watt, solar panels 101 can automatically shut off, as battery 602 is fully charged.

In one embodiment, solar panels 101 can be amorphous, while in another embodiment they can be pure sine. In one embodiment, solar panels 101 can comprise a modified sine wave or a pure sine wave, in another embodiment. While both types of solar panels 101 can produce alternating current for battery 602, pure sine wave embodiments can produce an electrical current represented by a sinusoidal wave smoothly alternating between a positive and negative charge. Graphical representation of a pure sine wave current would show rounded peaks and valleys. Conversely, a modified sine wave embodiment can produce an electrical current marked by abrupt peak voltages, dropping to flat line valleys. In a graphical representation, a modified sine wave current would appear as a flat line followed by a rectangular bar above the zero axis with an eventual flat line followed by a rectangular path below the zero axis. While a modified sine wave solar panel 101 may jolt batteries 602 to full capacity faster than a pure sine wave solar panel 101, pure sine wave solar panels can be more efficient for running batteries over an extended period of time. In addition, modified sine wave solar panels 101 may overheat batteries 602, cause inefficiency, and potentially damage some electrical devices plugged in, which are incompatible with modified sine wave inversion.

In another embodiment, amorphous silicon can be applied to solar panels 101. In addition, in one embodiment, a solar micro-inverter can be used, in which direct current is immediately translated into alternating current on site at the solar panel 101. Furthermore, to maximize efficiency of power yield, parabolic reflectors, solar concentrators, power optimizers and other mechanisms known by a person of ordinary skill in the art can be applied to solar panels 101 in coordination with battery 602.

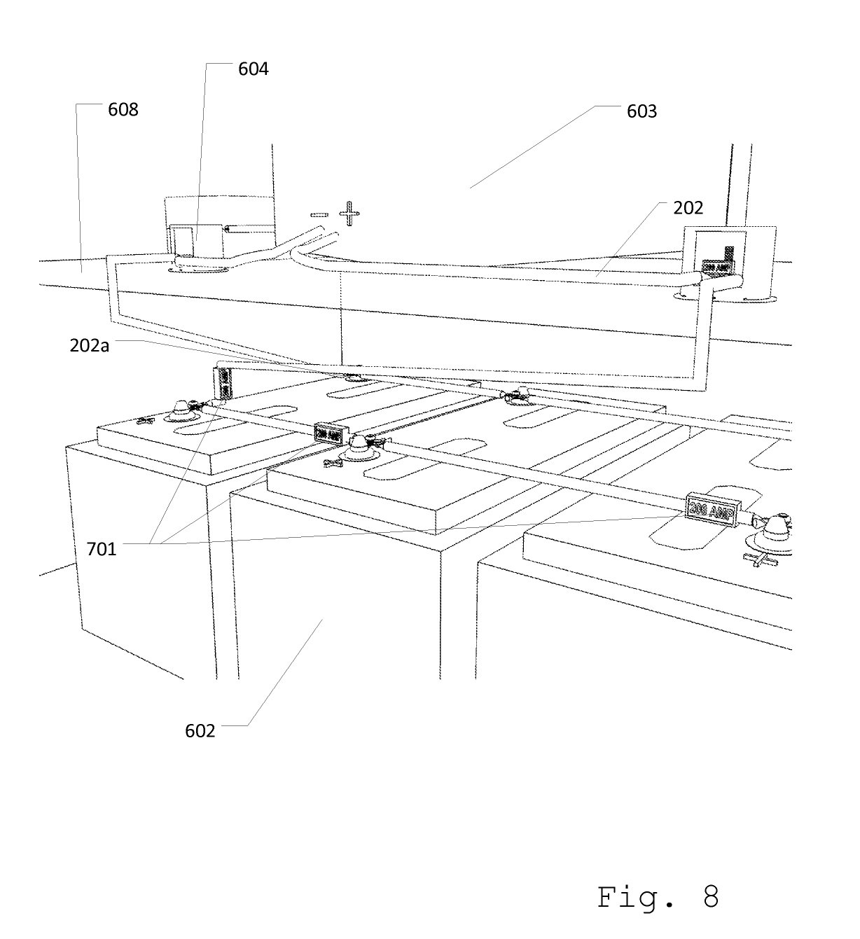

FIG. 8 illustrates an analog to digital converter 603. An analog-to-digital converter 603 can receive direct current and translate it into digital current by sampling volt level charges on a phase. When battery 602 is at low capacity, direct current can transfer from solar panels 101 to battery 602 to analog to digital converter 603 through wiring 202. In one embodiment, analog to digital converter 603 can be made to transfer 2500 watts, which is high-powered. An embodiment, in which A/D converter 603 can transfer 2500 watts can allow a more gradual, continuous running of power for electrical devices than a higher watt version, such as, but not limited to a 4500 watt embodiment of analog to digital converter 603. In an embodiment in which the analog to digital convertor 603 can be upgraded to a 10000 watt version, analog to digital convertor 603 can be capable of running power continuously, but not necessarily for as extended of a duration as a 2500 watt embodiment.

In one embodiment, analog to digital converter 603 can be mounted on to side of covering 102. Correspondingly, analog to digital converter 603 can be positioned within covering 102 to make plug-in appliances accessible to electrical sockets 609.

In one embodiment, analog to digital converter 603 display 610 can inform user of voltage and current levels of battery 602. Once activated, analog to digital converter 603 can display multiple readings, which can include an initial reading, as well as a reading, at which batteries are operating. In one embodiment, an initial reading of a plurality of “zeros” on display 610 when analog to digital converter 603 is activated can indicate that batteries 602 are balanced. Additionally, analog to digital converter 603 can display readings in terms of amps, watts and volts.

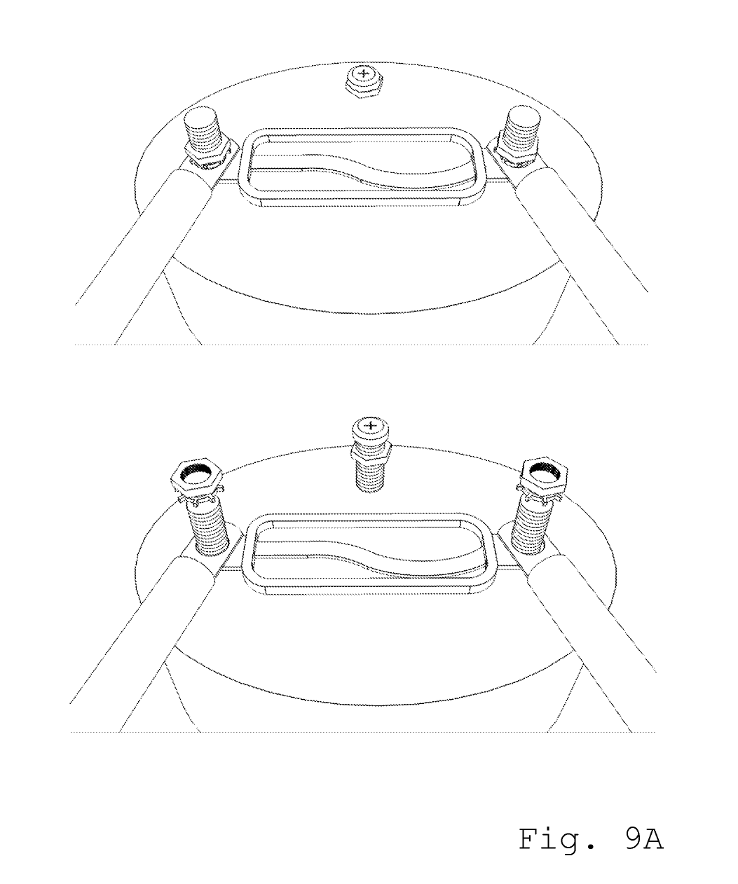

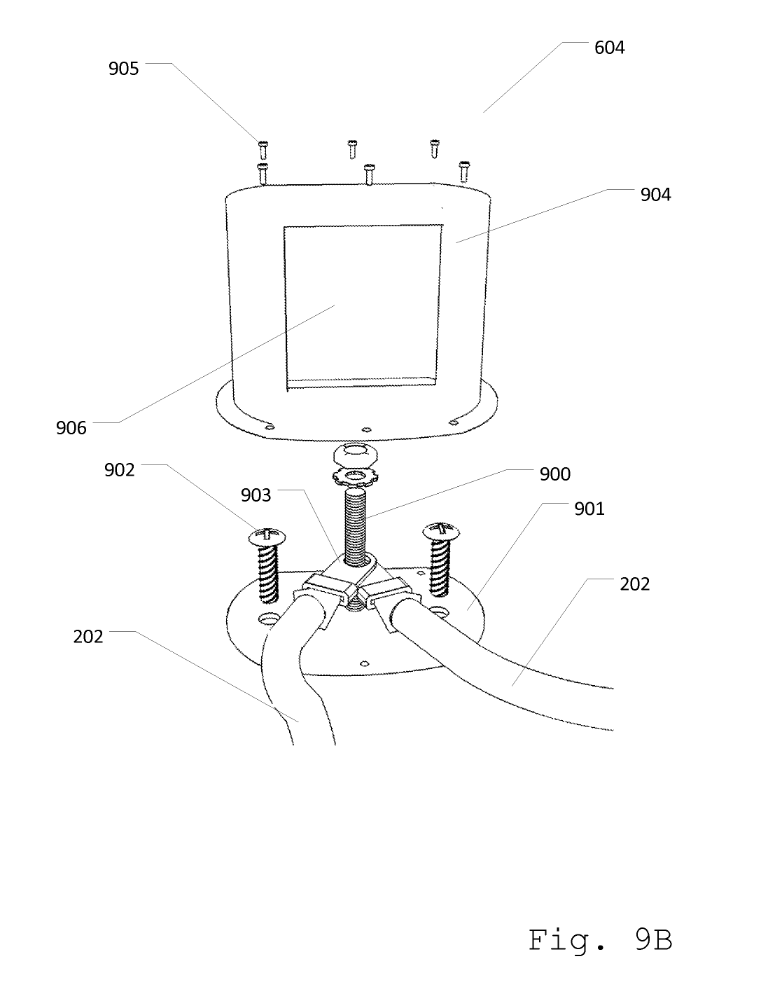

FIG. 9A illustrates an exploded view of breakers 701 and positive terminal 604a. Terminal 604 can comprise a terminal rod 900. In one embodiment, terminal rod 900 can comprise breaker 701. In another embodiment, terminal rod 900 can also function without breaker 701. Further, terminal rod 900 can be a metallic protrusion capable of conducting electricity. Terminal rod 900 can be affixed upon a rod base 901. Rod base 901 can be any material, such as, but not limited to, plastic, that can insulate terminal rod 900 from directly touching any surface of solar powered generator 100 and/or prevent current from being directed elsewhere. Rod base 901 can be affixed to covering 102 by base screws, in one embodiment.

Terminal rod 900 can be affixed upon rod base 901 along with breakers 701 by rod screws 902, in one embodiment. Terminal rod 900 with breakers 701 can be connected to wiring 202. In one embodiment, wiring 202 can comprise adapters 903 that can be fitted to width of terminal rod 900. As a result, wiring 202 can transfer current to terminal rod 900.

Terminal 604 can comprise a shell 904. Shell 904 can be a nonconductive cover surrounding terminal rod 900 and breakers 701 for safety and insulation of current from wiring 202. Shell 904 can be affixed onto rod base 901 by a plurality of shell screws 905, in one embodiment. Shell 904 can comprise a shell opening 906. Shell opening 906 can allow wiring 202 access to terminal rod 900, while shell 904 can protect terminal rod 900 and breakers 701.

Shell opening 906, can be a variety of sizes, dimensions, as desired by user and safety concerns.

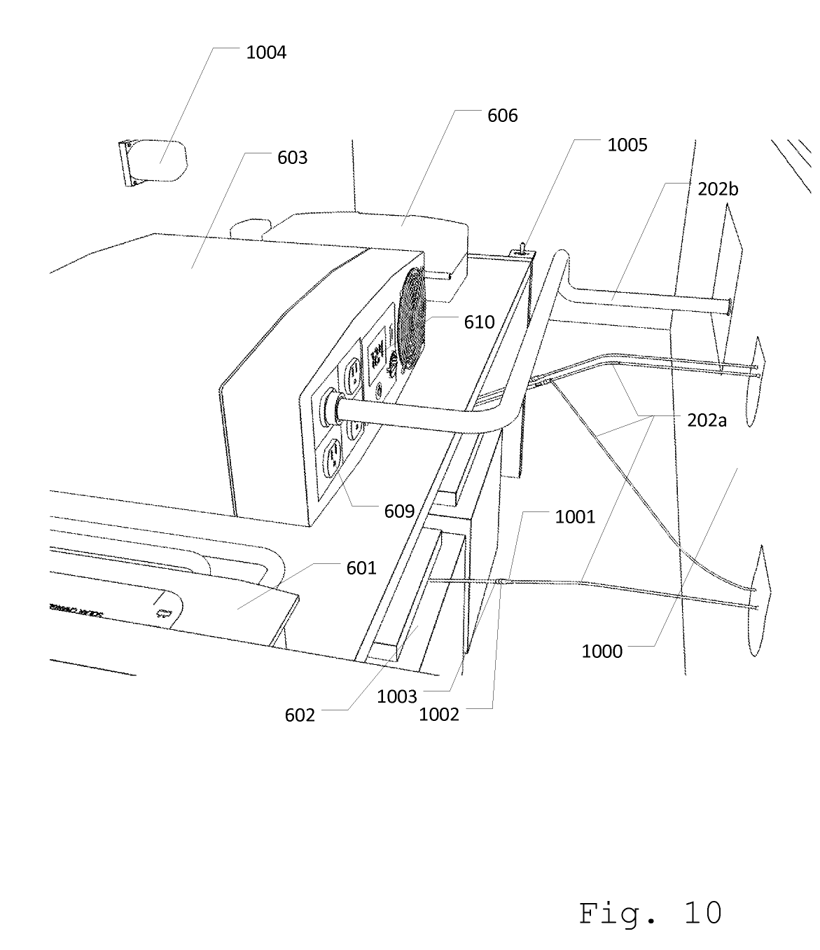

FIG. 10 illustrates a wire and breaker disconnecting system 1000. In one embodiment, wire and breaker disconnecting system 1000 can be attached to 12 volt outlets 111. In one embodiment, wiring 202 that can run directly to 12 volt outlets 111 can comprise breakers 701 attached anywhere between batteries 602 or A/D converter 603 to protect other batteries 602 in the sequence. Breakers 701 can be a junction point within wiring 202, at which, user can separate wiring 202 and safely disconnect flow of current to 12 volt outlet 111, so as to allow. Breakers 701 can comprise a nonconductive material, such as, but not limited to, plastic that can surround wiring 202.

In one embodiment, breakers 701 can comprise a male end 1002 and a female end 1003 embedded within wiring 202. While insertion of male end 1002 into female end 1003 can allow current to continue through wiring 202, wiring 202 can be disconnected by causing male end 1002 to break from female end 1003 by force. For example, user can pull male end 1002 from female end 1003 manually. As a result, user can be capable of stopping current flow of wiring 202 at desired point prior to reaching appliance plugged into 12-volt outlet 111.

In one embodiment, breakers 701 can be isolated away from 12-volt outlet 111 in case of electrical issues. Specifically, breakers 701 can be strategically placed at wiring 202 per each individual outlet so that user can shut off one 12-volt outlet 111 while allowing another 12-volt outlet 111 to continue. In another embodiment, breakers 701 can have groups of wiring 202 routed together at one male end 1002 and female end 1003 so that user can disconnect wiring 202 from multiple or each 12-volt outlet 111, as needed. While, in one embodiment, wire disconnecting system 1000 can be attached to both 12 volt outlets 111, breakers 701 can also be placed in wiring 202 leading to power outlets 104, as well. In another embodiment, breakers 701 also can be placed in wiring 202 to both 12 volt outlets 11 and power outlets 104.

Breakers 701 can be compatible with the transferring at least 20 watts, in one embodiment. In another embodiment, breakers 701 can be made to transfer at least 40 watt to allow powering of both power outlets 104 and 12-volt outlets 111 in combination. In one embodiment, at least one breaker 701 can be connected from positive pole of battery 602 to 12-volt outlets 111 and/or power outlet 104.

Furthermore, a signal light 1004 can be situated within inner recess 600. In on embodiment, signal light 1004 can allow for illumination. In another embodiment, signal light 1004 can concurrently be used to communicate electrical status and/or electrical issues regarding solar-powered generator 100. In one embodiment, signal light 1004 can protrude from inner recess 600 of covering 102. In one embodiment, signal light 1004 switch 1005 can allow for a light to turn on/off to allow for viewing of all components housed in inner recess.

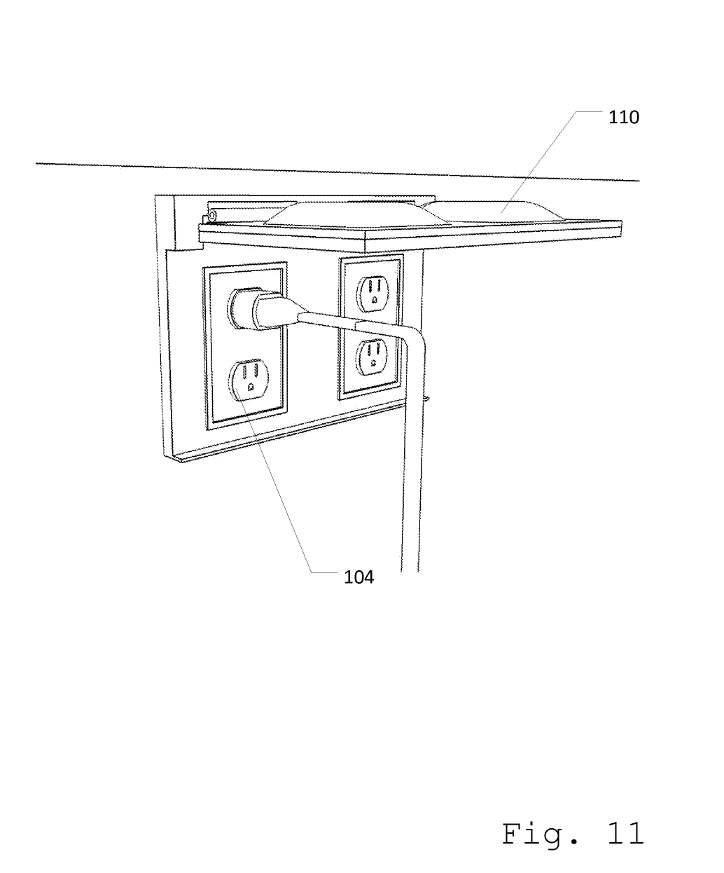

FIG. 11 illustrates a power outlet 104. Power outlet 104 can be affixed to covering 102 on portable solar-powered generator 100 and can be connected to analog to digital converter 603 by wiring 102. Once electrical signal data is converted into digital format, usable energy can be transferred from analog to digital converter 603 to power outlet 104. Power outlet 104 can comprise a female socket, in which a male prong can be mated to power outlet 104, a wall plate affixing power outlet 104 to covering 102, and a cover to protect socket.

In one embodiment, a socket cover 110 can also prevent moisture from building up within wiring, further making portable solar-powered generator 100 water resistant. In particular, socket cover 110 for power outlet 104 can comprise on solid piece, in one embodiment, or multiple individualized covers, separately covering each individual socket, in another embodiment. In one embodiment, socket cover 110 can comprise two separate halves. When one side of power outlets 104 is in use, other half can continue to be protected by socket cover 110.

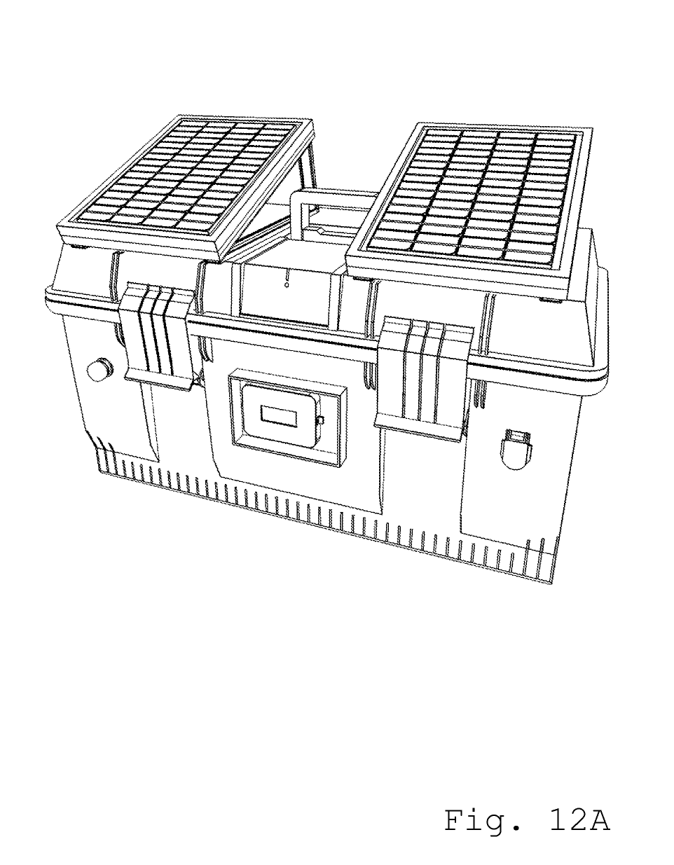

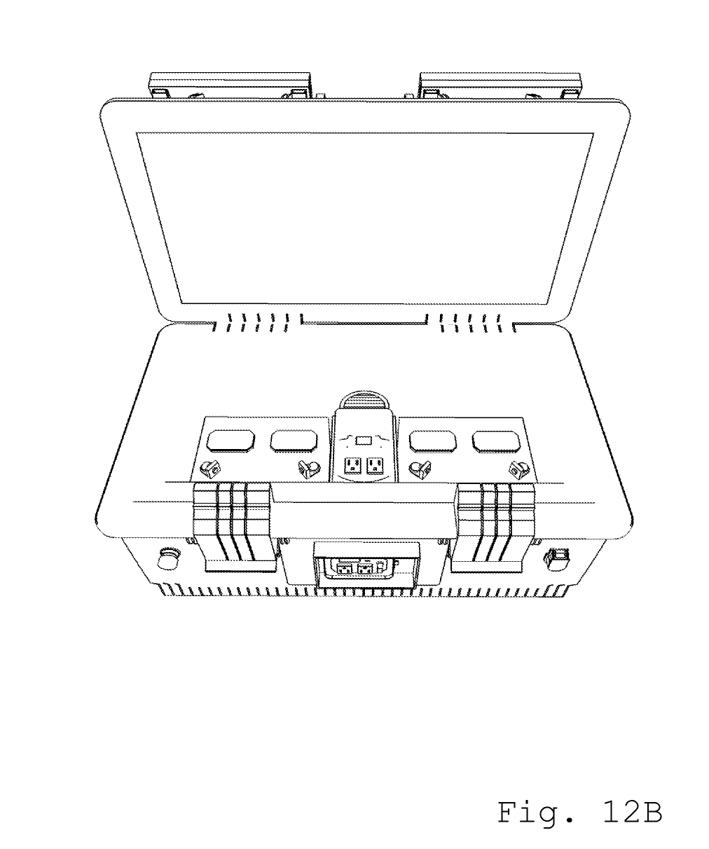

FIG. 12A illustrates an embodiment of a handheld portable solar-powered generator 100. In this embodiment, portable solar-powered generator 100 can be light and small enough to be hand carried. Solar panels 101 can be mounted on top surface of coverings 102. In one embodiment, top surface of covering 102 can be door 105. Door 105 can further comprise lock 109 that secure portable-solar powered generator 100 installed within coverings 102.

FIG. 12B illustrates an opened handheld portable solar-powered generator 100 comprising wirings 202, controller 601, and batteries 602. Wirings 202 can connect controller 601 with solar panels 101 and batteries 602. Wiring 202 can transfer power gathered from solar panels 101 to controller 601. Power outlet 104 can mount controller 601, in one embodiment. As such, plug insert can only be accessible through opening door 105 of portable solar-powered generator. In another embodiment, power outlet 104 can be installed at outer surface of coverings 102, therefore making it easily accessible.

Various changes in the details of the illustrated operational methods are possible without departing from the scope of the following claims. Some embodiments may combine the activities described herein as being separate steps. Similarly, one or more of the described steps may be omitted, depending upon the specific operational environment the method is being implemented in. It is to be understood that the above description is intended to be illustrative, and not restrictive. For example, the above-described embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. An improved portable solar-powered generator comprising
a controller system
a covering, wherein said covering comprises a side surface, an inner recess capable of encasing said controller system, and an opening at a top surface; and
a plurality of solar panels mountable at said covering.

2. The system of claim 1, further comprising
a door attached on said top surface, said door configured to open and close said opening, further wherein top portion of said door comprises said solar panels
a side panel attached on said side surface, further wherein top portion of said side panel comprises said solar panel.

3. The system of claim 2, wherein said door connects to said top surface by hinges.

4. The system of claim 3, wherein said door comprises a propping mechanism, said propping mechanism comprising
a plurality of latches connected to said door
a pin, said pin capable of locking said hinges.

5. The system of claim 2, wherein said side panel connects to said side surface by hinges.

6. The system of claim 5, wherein said side panel comprises a pneumatic closer, said pneumatic closer attached to bottom surface of said side panel.

7. The system of claim 6, wherein said pneumatic closer comprises a hydraulic support

8. The system of claim 6, wherein said pneumatic closer connects to said side panel through a track system.

9. The system of claim 8 wherein said track system comprises
a slot; and
a track mateable with said slot, further wherein said track comprises a track attachment, said track attachment linkable to said slot

10. The system of claim 9, wherein said track attachment comprises a lock that fixes said track into a spot on said slot.

11. The system of claim 6, wherein said pneumatic closer connects to said side panel through a cranking mechanism.

12. The system of claim 11, wherein said cranking mechanism comprises

13. The system of claim 1, wherein said controller system further comprises
a battery
an analog to digital converter
a plurality of wirings connecting said batteries, and said analog to digital converter.
a plurality of power outlets mounted said coverings, further wherein said power outlets connected said analog to digital converter through said wirings. The system of claim 13, wherein said battery comprises a lithium-ion battery.

14. The system of claim 13, wherein said wiring comprises a wire and breaker disconnecting system comprising
a plurality of breakers attached at junctions of said wiring, said breakers comprising
a male end; and
a female end, said male end mateable said female end.

15. The system of claim 1, wherein said covering comprises a water resistant material

16. The system of claim 1, wherein said covering comprises an insulating material

17. The system of claim 1, wherein said solar panel comprises a pure sine inverter.

18. The system of claim 1, wherein said solar panel comprises a modified sine inverter.
